(19) United States
(12) Patent Application Publication
(10) Pub. No.: US 2005/0233076 A1
(43) Pub. Date: Oct. 20, 2005

(54) Apparatus for supporting substrate

(75) Inventors: Shao-Ming Hsu, Miao-Li (TW); Ching-Lung Wang, Miao-Li (TW); Wen-Cheng Hsu, Miao-Li (TW); Yu-Ying Chan, Miao-Li (TW); Tseng-Kuei Tseng, Miao-Li (TW); Ho-Li Hsieh, Miao-Li (TW); Chen-Kun Teng, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/111,100

(22) Filed: Apr. 20, 2005

(30) Foreign Application Priority Data
Apr. 20, 2004 (TW) 93110938

(51) Int. Cl. C23C 14/00; C23C 14/32

(52) U.S. Cl. 427/226; 427/331

(57) ABSTRACT

An apparatus (20) for supporting a substrate (S2) includes a number of slats (28), a number of connecting blocks (24) separately positioned on the slats, and a number of soft sleeves (22) connected with the connecting blocks, respectively. Because top surfaces of the soft sleeves are shaped as annular, the force applied between the substrate and the soft sleeves is distributed, and is reduced at each contact point. The surface of the substrate is hardly if at all deformed by the soft sleeves, thereby reducing the risk of or even altogether preventing the formation of undulations. The quality of the pattern to be processed is improved.

### FIELD OF THE INVENTION

The present invention relates to an apparatus for supporting a substrate, and particularly to an apparatus for supporting a substrate coated with a coating liquid that is an object to be dried.

### BACKGROUND

During a process of fabricating a color filter for a liquid crystal display (LCD), a glass substrate is applied with coating liquid such as photoresist liquid and is dried to form a desired pattern by such a photolithography or the like. As coating liquid application system, for example, a spin coating system, a knife coating system, a roll coating system, or the like can be employed. In any case of application such as mentioned above, a drying process for drying a coating film is required before a pattern forming process. Conventionally, for an object to be dried such as a glass substrate coated with coating liquid, a low pressure dryer (LPD) or a vacuum drying apparatus or the like have been used. When the glass substrate is placed in the LPD or the vacuum drying apparatus, a substrate supporting apparatus is necessary to support the glass substrate to be dried.

Referring to FIG. 5, this shows a vacuum chamber 11 of a vacuum drying apparatus as disclosed in U.S. Pat. No. 6,473,995. The vacuum chamber 11 includes a substrate supporting apparatus 10 positioned therein. The substrate supporting apparatus 10 includes a platform 14, an under-plate 15, and a plurality of support pins 16. The under-plate 15 is provided on a bottom part of the vacuum chamber 11 through the platform 14. The support pins 16 are provided on the under-plate 15, and are for floating a substrate S1 coated with the coating liquid that is an object to be dried.

However, because a bottom surface of the substrate S1 is supported by the support pins 16, the force applied on the bottom surface of the substrate S1 is concentrated at each contact point between the substrate S1 and the support pins 16. The bottom surface may be slightly deformed according to the concentrated force. As a result, the surface of the coating film is liable to form undulations. This can influence the quality of the pattern to be processed thereafter.

What is needed, therefore, is an apparatus for supporting substrate that can relieve the influence of the force at the contact points.

### SUMMARY

An apparatus for supporting a substrate includes a plurality of slats, a plurality of connecting blocks separately positioned on each slat, and a plurality of soft sleeves respectively fixed on each connecting block. Because top surfaces of the soft sleeves are shaped as annular, the force applied between the substrate and the soft sleeves is averaged and reduced at each contact point. The surface of the substrate is hardly if at all deformed by the soft sleeves, thereby reducing the risk of or even altogether preventing the formation of undulations. The quality of the pattern to be processed is improved.

Other objects, advantages, and novel features become more apparent from the following detailed description of a preferred embodiment when taken in conjunction with the accompanying drawings, in which:

### BRIEF DESCRIPTION OF THE DRAWINGS

FIG. 1 is an isometric view of an apparatus for supporting substrate according to a preferred embodiment of the present invention;

FIG. 2 is an enlarged view of a circled portion II of FIG. 1;

FIG. 3 is a schematic, isometric view of the apparatus of FIG. 1 positioned in a vacuum chamber and supporting a substrate thereon;

FIG. 4 is a right elevation view of FIG. 3; and

FIG. 5 is a schematic, isometric view of a conventional apparatus for supporting substrate, which is positioned in a vacuum chamber.

### DETAILED DESCRIPTION OF PREFERRED EMBODIMENTS

Reference will now be made to the drawings to describe a preferred embodiment of the present invention in detail.

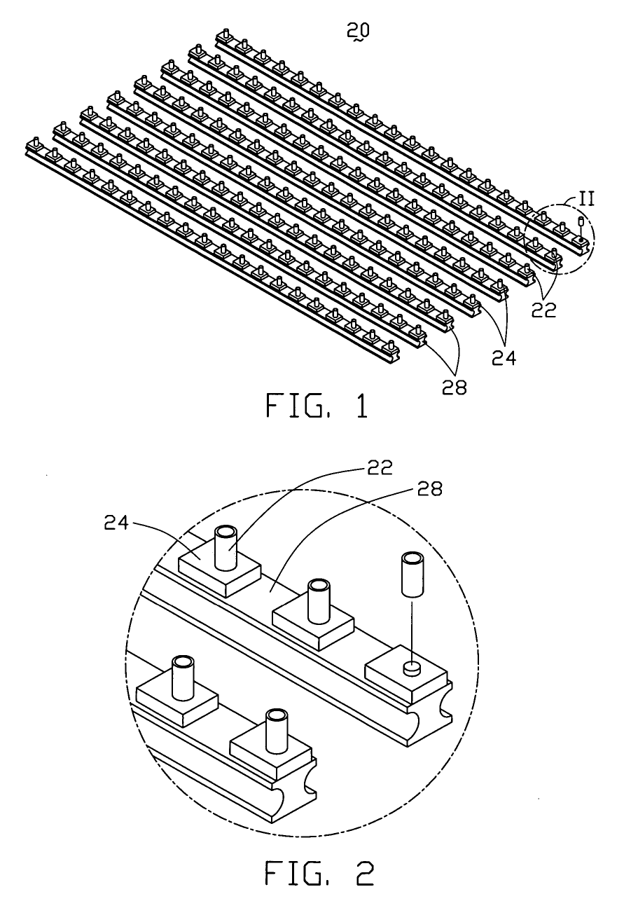

Referring to FIGS. 1-2, an apparatus 20 for supporting substrate in accordance with a preferred embodiment of the present invention includes a plurality of elongated support slats 28, a plurality of connecting blocks 24, and a plurality of soft sleeves 22. The support slats 28 are parallel to each other. The connecting blocks 24 are uniformly and separately fixed on a top surface of the support slats 28. Each soft sleeve 22 is connected with one connecting blocks 24. Thus, the soft sleeves 22 form an array, and the top surfaces of the soft sleeves 22 are in the same plane.

The support slats 28 and the connecting blocks 24 can be made of metal material, for example, aluminum, copper, or the like. The soft sleeves 22 can be made of plastic material, for example, polyimide, or the like. In addition, the support slats 28 and the connecting blocks 24 can be made of nonmetal material.

The connecting blocks 24 can be fixed on the support slats 28 in the follow manner, for example, adhesive bonding, welding, bolted connection, or the like. The soft sleeves 22 can be connected with the connecting blocks 24 in the following manner, for example, sleeve joint, adhesive bonding, or the like.

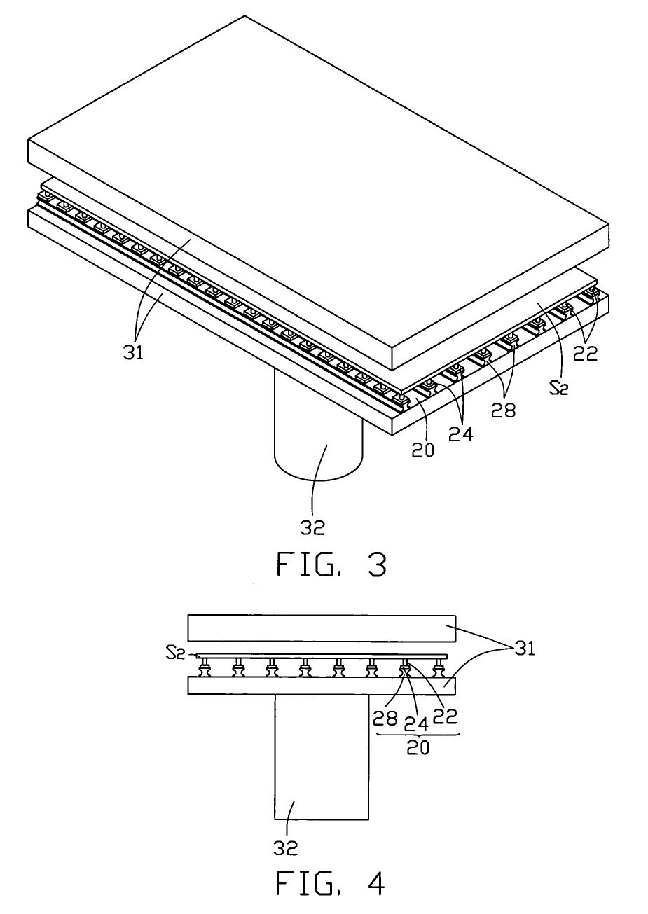

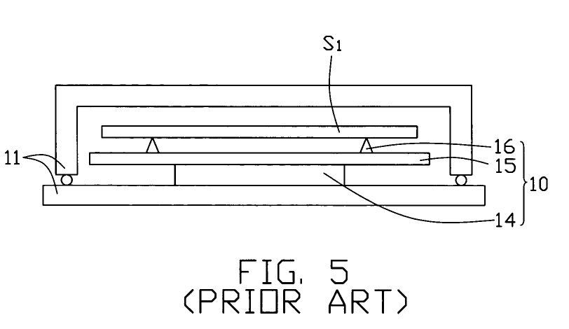

Referring to FIGS. 3-4, in using, the apparatus 20 is placed in a low pressure chamber 31, and a glass substrate S2 coated with coating liquid to be dried is placed on the top surfaces of the soft sleeves 22. After the low pressure chamber 31 is sealed, a vacuum pump 32 is actuated to lower the pressure of the chamber 31. Because the gas in the low pressure chamber 31 is exhausted, the solvent of the coating liquid is evaporated gradually until the coating liquid is dried.

Because the top surfaces of the soft sleeves 22 are shaped as annular, and the soft sleeves 22 are separately arranged, the force applied between the substrate S2 and the soft sleeves 22 is averaged and reduced at each contact point. The surface of the substrate S2 may hardly be deformed by the soft sleeves 22, and are prevented form undulations. The quality of the pattern to be processed is improved.

It is to be understood, however, that even though numerous characteristics and advantages of the preferred embodiment have been set forth in the foregoing description, together with details of the structure and function of the preferred embodiment, the disclosure is illustrative only, and changes may be made in detail, especially in matters of shape, size and arrangement of parts within the principles of the invention to the full extent indicated by the broad general meaning of the terms in which the appended claims are expressed.

1. An apparatus for supporting a substrate, comprising:
a plurality of slats;
a plurality of connecting blocks separately positioned on each slat and
a plurality of soft sleeves respectively fixed on each connecting block.

2. The apparatus as recited in claim 1, wherein the slats and the connecting blocks are made of metal, and the soft sleeves are made of soft plastic.

3. The apparatus as recited in claim 1, wherein the slats and the connecting blocks are made of aluminum, and the soft sleeves are made of polyimide.

4. The apparatus as recited in claim 1, wherein each connecting block is adhered to the corresponding slat.

5. The apparatus as recited in claim 1, wherein each connecting block is soldered on the corresponding slat.

6. The apparatus as recited in claim 1, wherein each connecting block is screwed on the corresponding slat.

7. The apparatus as recited in claim 1, wherein each of the soft sleeves is fittingly attached on the corresponding connecting block.

8. The apparatus as recited in claim 1, wherein each soft sleeve is adhered to the corresponding connecting block.

9. A method of supporting a substrate, comprising:
providing a plurality of slats;
positioning a plurality of connecting blocks separately on each slat;
a plurality of soft sleeves respectively fixed on said connecting blocks, respectively; and
locating said substrate upon said soft sleeves in an even manner.

10. An apparatus assembly comprising:
a plurality of connecting blocks arranged in matrix;
a plurality of soft sleeves respectively attached on top ends of the connecting blocks, respectively; and
a substrate seated upon said soft sleeves in an even manner.
